(19) United States
(12) Patent Application Publication
(10) Pub. No.: US 2022/0020927 A1
(43) Pub. Date: Jan. 20, 2022

(54) METHOD FOR MANUFACTURING A DISPLAY PANEL, A DISPLAY PANEL AND A TRANSFER DEVICE

(71) Applicant: BOE TECHNOLOGY GROUP CO., LTD., Beijing (CN)

(72) Inventor: Yujun ZHANG, Beijing (CN)

(21) Appl. No.: 16/499,577

(22) PCT Filed: Apr. 29, 2019
(86) PCT No.: PCT/CN2019/085050

§ 371 Date: Sep. 16, 2021

(30) Foreign Application Priority Data
May 7, 2018 (CN) 201810427816.0

(51) Int. Cl. H01L 51/00; H01L 27/32; H01L 51/56

(52) U.S. Cl. CPC H01L 51/0021; H01L 51/56; H01L 27/3276

(57) ABSTRACT

A method for manufacturing a display panel, a display panel, and a transferring device are provided. Metal liquid is formed on a side surface of the base substrate to form a first region to be bonded. After curing, the second connecting lines are formed by etching such that the second connecting lines correspond to and connect to the first connecting lines disposed on the front surface of the base substrate, thereby providing the side bonding of the display panel. By using an integral transferring and etching method, the line width and pitch of the connecting lines in the region to be bonded can be reduced, which makes it suitable for full-size display panels with a wider range of applications, especially for products with high resolution.

### TECHNICAL FIELD

The present disclosure is directed to a displaying technical field, and particularly relates to a manufacturing method of a display panel, a display panel and a transferring device.

### BACKGROUND

With development of displaying technology, narrow borders have become the development trend of display panels. At present, the borders of display panels on the non-bonding side can be made to 0.9 mm, however, the borders on the bonding side are still wider due to presence of the bonding area.

In addition, the existing method for preparing the bonding region by a transferring strategy can only be applied to those products with low resolution, namely the transferring that provides connecting lines with a pitch and a line of larger than 60 μm, but cannot be applied to those products with high resolution.

### SUMMARY

The present disclosure provides the following technical solutions.

A method for manufacturing a display panel, comprising the following steps:

providing a base substrate having a first surface, wherein a plurality of first connecting lines is arranged on at least one side of the first surface;

transferring a metal liquid for forming second connecting lines to a second surface of the base substrate by using a transferring device, to cover entire area of a first region to be bonded, wherein the second surface is connected to the first surface; and

curing the metal liquid in the first region to be bonded, and etching to form a plurality of second connecting lines, such that each of the second connecting lines corresponds to and connects to each of the first connecting lines.

Optionally, the etching to form the plurality of second connecting lines comprises: forming the plurality of second connecting lines by laser etching.

Optionally, the method further comprises: transferring the metal liquid onto a third surface of the base substrate by the transferring device, to form a second region to be bonded, wherein the third surface is disposed opposite to the first surface and is connected to the second surface; and

curing the metal liquid in the second region to be bonded, and etching to form a plurality of third connecting lines, such that each of the third connecting lines corresponds to and connects to each of the second connecting lines.

Optionally, the curing conditions for curing the metal liquid in the first region to be bonded and/or curing the metal liquid in the second region to be bonded include:

a curing temperature of 100° C. to 130° C., optionally with a curing time of 8 to 10 minutes.

Optionally, the etching to form the plurality of third connecting lines comprises: forming the plurality of third connecting lines by laser etching.

Optionally, the transferring device comprises a container for containing the metal liquid, and a transferring head.

Optionally, the container is an oil cup, and the metal liquid is injected into the oil cup prior to the transferring, wherein the oil cup preferably has an undivided integral groove structure.

Optionally, the transferring head has the same size as the size of the first region to be bonded.

Optionally, transferring the metal liquid for forming second connecting lines to the second surface of the base substrate by using the transferring device and/or transferring the metal liquid to the third surface of the base substrate by using the transferring device comprise(s): transferring the metal liquid from the container to the transferring head of the transferring device, and forming the metal liquid on the second surface of the base substrate and/or the third surface of the base substrate by using the transferring head.

A display panel comprises a base substrate, and the base substrate comprising:

a first surface provided with a plurality of first connecting lines at at least one side;

a second surface connected to the first surface, the second surface comprises a first region to be bonded, wherein a plurality of second connecting lines is arranged in the first region to be bonded, and each of the second connecting lines corresponds to and connects to each of the first connecting lines; and

a third surface disposed opposite to the first surface, the third surface comprises a second region to be bonded, wherein a plurality of third connecting lines is arranged in the second region to be bonded, and each of the third connecting lines corresponds to and connects to each of the second connecting lines.

Optionally, the first connecting line, the second connecting line, and the third connecting line have a line width of 10 μm to 30 μm; and/or,

each of the first connecting lines, each of the second connecting lines, and each of the third connecting lines have a pitch of 10 μm to 30 μm therebetween.

Optionally, the display panel is an OLED display panel.

Optionally, the first surface comprises a peripheral region, and the plurality of first connecting lines are arranged on one side of the peripheral region.

Optionally, the peripheral region has a width less than or equal to 1 mm, such as less than or equal to 0.9 mm, less than or equal to 0.8 mm, or even less than or equal to 0.7 mm.

A transferring device applied to the method for manufacturing any of the above display panels, comprising: a container for containing the metal liquid, a transferring head, and an etching apparatus for forming the second connecting lines and/or the third connecting lines, wherein the container has an undivided integral groove structure for containing the metal liquid.

Preferably, the transferring head has the same size as a size of the first region to be bonded.

Preferably, the etching apparatus includes a laser etching apparatus, and the laser etching apparatus generates a laser spot with a width of 10 μm to 30 μm.

### DESCRIPTION OF THE DRAWINGS

FIG. 1 is a flowchart showing the method for manufacturing the display panel according to an embodiment of the present disclosure;

FIG. 2 is a flowchart showing the method for manufacturing the display panel according to another embodiment of the present disclosure;

FIG. 3 is a schematic view showing a structure of the first surface of the display panel according to some examples of the present disclosure;

FIG. 4 is a schematic view showing a structure of the second surface of the display panel according to some examples of the present disclosure;

FIG. 5 is a schematic view showing a structure of the third surface of the display panel according to some examples of the present disclosure;

FIG. 6 is a schematic view showing a structure of the transferring apparatus according to some examples of the present disclosure.

### REFERENCE NUMBERS

1. base substrate 2. COF substrate 11. the first surface
12. peripheral region 13. the first connecting line 14. the second surface
15. the first region to be bonded 16. the second connecting line
17. the third surface 18. the second region to be bonded
19. the third region to be bonded

### DETAILED DESCRIPTION OF THE EMBODIMENTS

The technical solutions of the present disclosure will be described clearly and completely in conjunction with the drawings of the present disclosure. It is obvious that the described embodiments are some, but not all, of the embodiments of the present disclosure. All other embodiments obtained by one of ordinary skill in the art without involving any inventive effort are within the scope of the present disclosure.

For the display panel, the finished connecting lines can be transferred to the side surface of the base substrate to achieve the side bonding. Specifically, each region corresponding to each connecting line is formed in an oil cup of a transferring device. A metal liquid is contained in each region respectively, and the metal liquid in each region is dipped respectively by the transferring head, and each connecting line is formed on the side surface of the base substrate. In this process, since the pitch of the adjacent connecting lines is small, and the connecting line pattern is not yet cured, the adjacent connecting lines tend to be interconnected, resulting in a failure of the transferring. Therefore, this method can only be applied to those products with low resolution, namely the transferring that provides connecting lines with the pitch and the line width larger than 60 μm, but cannot be applied to those products with high resolution.

To solve the problem in the prior art, a method for manufacturing a display panel, the display panel, and a transferring device are provided so as to at least partially solve the problem that the existing transferring strategy cannot be applied to those products with high resolution and/or further reduce the size of a border of the display panel.

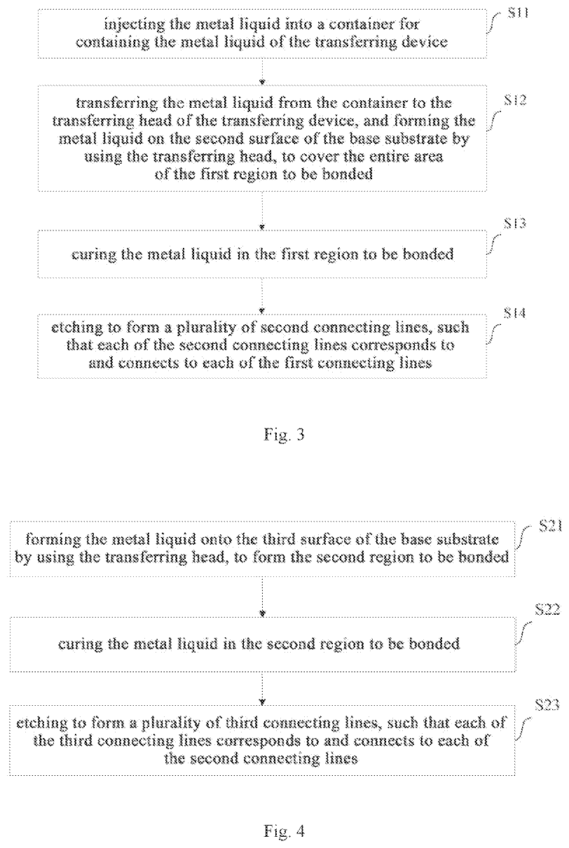

In one embodiment, a method for manufacturing a display panel is provided. As shown in FIG. 3, the display panel comprises a base substrate 1 having a first surface 11. The first surface 11 may include a perimeter region 12. A plurality of first connecting lines 13 may be arranged at one side of the peripheral region 12. The side where the first connecting line 13 is located is the side to be bonded of the display panel. The first connecting line 13 is the connecting line of the bonded area, and the first surface 11 may be a front side of the base substrate 1.

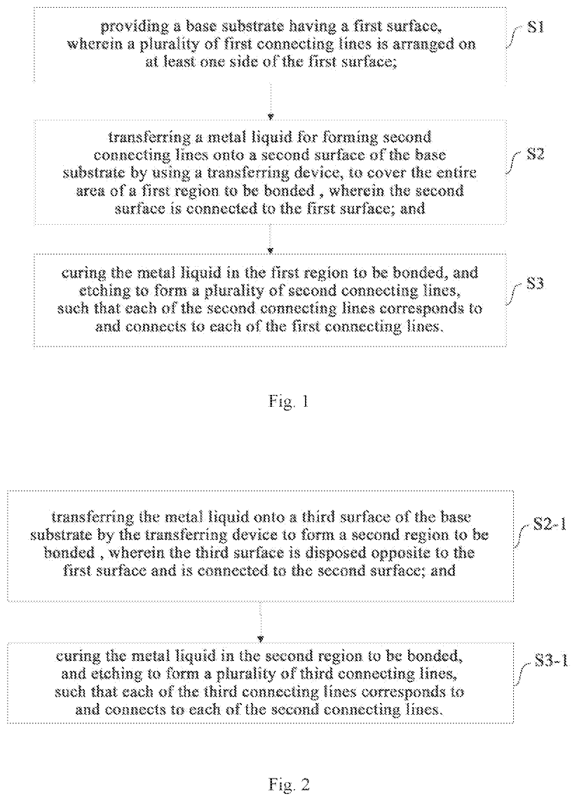

As shown in FIG. 1, the method for manufacturing the display panel according to the present disclosure may comprise the following steps:

S1-providing a base substrate having a first surface, wherein a plurality of first connecting lines are arranged on at least one side of the first surface;

S2-transferring a metal liquid for forming second connecting lines to a second surface of the base substrate by using a transferring device, to cover the entire area of a first region to be bonded, wherein the second surface is connected to the first surface; and

S3-curing the metal liquid in the first region to be bonded, and etching to form a plurality of second connecting lines such that each of the second connecting lines corresponds to and connects to each of the first connecting lines.

The first region to be bonded may be located on the second surface.

As shown in FIGS. 3, 4 and 5, in one embodiment, the method for manufacturing the display panel may comprise the following steps:

Step S11: injecting the metal liquid into a container for containing the metal liquid (for example, an oil cup) of the transferring device.

Specifically, the transferring device may comprise a container for containing the metal liquid (for example, an oil cup) and a transferring head. The container for containing the metal liquid may be an oil cup. The oil cup may have an undivided integral groove structure, in which the metal liquid for forming the connecting lines may be contained. Preferably, the metal may be Ag, Au, Cu, Al and the like.

Step S12: transferring the metal liquid from the container to the transferring head of the transferring device, and forming the metal liquid on the second surface of the base substrate by using the transferring head, to cover the entire area of the first region to be bonded. The second surface is connected to the first surface.

Transferring the metal liquid from the container to the transferring head of the transferring device comprises: dipping the metal liquid in the container by using the transferring head, sucking the metal liquid in the container by a suction structure, and injecting the metal liquid into the transferring head by using a pipetting apparatus.

As shown in FIGS. 3 and 4, the second surface 14 of the base substrate 1 is connected to the first surface 11, that is, the second surface 14 is the side surface of the base substrate 1.

Preferably, the transferring head has a size smaller than the size of the oil cup, and the size of the transferring head is the same as the size of the first region to be bonded 15. Specifically, the metal liquid is dipped from the oil cup by using the transferring head, and he metal liquid is transferred to the second surface 14 of the base substrate 1, thereby transferring the metal liquid for forming the plurality of second connecting lines 16, as a whole, to the second surface 14 of the base substrate 1 to form the first region to be bonded 15.

Preferably, the first region to be bonded 15 has a size of 10*20 mm.

Step S13: curing the metal liquid in the first region to be bonded 15.

Preferably, the curing conditions include a curing temperature of 100° C. to 130° C. and a curing time of 8 to 10 minutes.

Step S14: etching to form a plurality of second connecting lines, such that each of the second connecting lines corresponds to and connects to each of the first connecting lines.

Specifically, the transferring device may further comprise a laser head, and the second connecting lines may be formed by laser etching. As shown in FIG. 5, the laser head of the transferring device is controlled to move within the first region to be bonded 15, and the first region to be bonded 15 is irradiated with the laser generated by the laser head to form the plurality of second connecting lines.

When the metal liquid in the first region to be bonded 15 is cured, a whole metal region is formed, and the laser head moves along the previously programmed pattern. Under the irradiation of the high-energy laser generated by the laser head, the metal is vaporized and etched out via absorbing the energy of the laser, while the metal unexposed to the laser is left, thereby providing the pattern to form the second connecting lines 16. It should be noted that since the focal plane of the laser is focused on the metal region (i.e., the first region to be bonded 15), no damage is caused to the surface of the base substrate 1 other than the first region to be bonded 15.

Since the second surface 14 (i.e., the side surface of the base substrate 1) is connected to the first surface 11 (i.e., the front surface of the base substrate 1), the second connecting lines 16 formed on the second surface 14 correspond to the first connecting lines 13 formed on the first surface 11, so that the second connecting lines 16 and the first connecting lines 13 are connected to each other at the connecting position between the second surface 14 and the first surface 11. As such, the region to be bonded which is positioned initially in the first surface 11 is transferred to the second surface 14.

It can be seen from the above steps S11-S14 that the metal liquid is formed on the side surface of the base substrate 1 to form the first region to be bonded 15, and the second connecting lines 16 that correspond and connect to the first connecting lines 13 on the front surface of the base substrate 1 are formed by etching after curing to achieve the side bonding of the display panel. The embodiments of the present disclosure can be applied to liquid crystal display panels and OLED (Organic Light-Emitting Diode) panels. By using an integral transferring and etching method, the line width and pitch of the connecting lines in the region to be bonded can be reduced, which makes it suitable for full-size display panels with a wider range of applications, especially for those products with high resolution.

Further, as shown in FIG. 2, the method for manufacturing the display panel may further comprise the following steps:

S2-1: transferring the metal liquid onto a third surface of the base substrate by the transferring device to form a second region to be bonded, wherein the third surface is disposed opposite to the first surface and is connected to the second surface; and

S3-1: curing the metal in the second region to be bonded, and etching to form a plurality of third connecting lines, such that each of the third connecting lines corresponds to and connect to each of the second connecting lines.

More specifically, according to another embodiment of the present disclosure, as shown in FIG. 4, after injecting the metal liquid into the container (such as an oil cup) of the transferring device (i.e., step 1), the method may further comprise:

Step S21: forming the metal liquid onto the third surface of the base substrate by using the transferring head, to form the second region to be bonded.

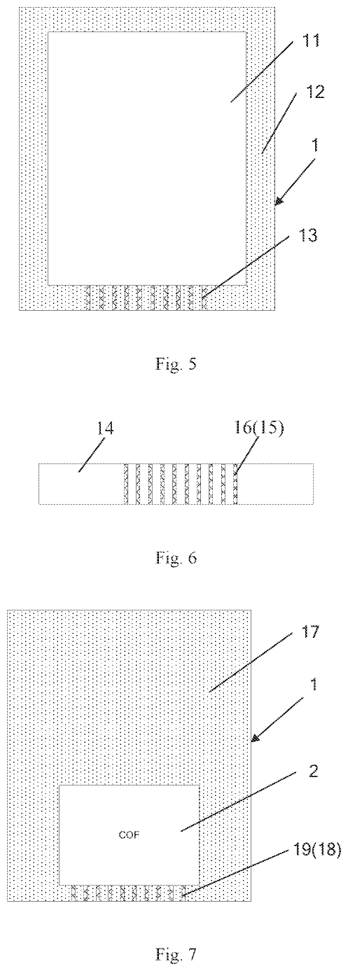

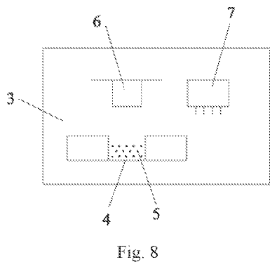

As shown in FIGS. 7 and 6, the third surface 17 of the base substrate 1 is disposed opposite to the first surface 11 and is connected to the second surface 14, that is, the first surface 11 is the front surface of the base substrate 1, and the third surface 17 is the back surface of the base substrate 1.

Specifically, the transferring head has a size smaller than the size of the oil cup, and the size of the transferring head is the same as the size of the second region to be bonded 18. Specifically, the metal liquid is dipped from the oil cup by using the transferring head, and the metal liquid is embossed onto the third surface 17 of the base substrate 1, thereby integrally transferring the metal liquid for forming the plurality of third connecting lines 19 onto the third surface 17 of the base substrate 1, and forming the second region to be bonded 18. Preferably, the second region to be bonded 18 is located on the side where the third surface 17 is connected to the second surface 14, and the second region to be bonded 18 is positioned corresponding to the position of the first connecting lines 13.

Step S22: curing the metal liquid in the second region to be bonded.

Preferably, the curing conditions include a curing temperature of 100° C. to 130° C. and a curing time of 8 to 10 minutes.

Step S23: etching to form a plurality of third connecting lines, such that each of the third connecting lines corresponds to and connects to each of the second connecting lines.

Specifically, the plurality of third connecting lines may be formed by laser etching, that is, the laser head of the transferring device is controlled to move within the second region to be bonded 18, and the second region to be bonded 18 is irradiated with the laser generated by the laser head, thereby forming the plurality of third connecting lines.

When the metal liquid in the second region to be bonded 18 is cured, an integral metal region is formed, and the laser head moves along the previously programmed pattern. Under the irradiation of the high-energy laser generated by the laser head, the metal is vaporized and etched out via absorbing the energy of the laser, while the metal unexposed to the laser is left, thereby providing the pattern to form the third connecting lines 19. It should be noted that since the focal plane of the laser is focused in the metal region (i.e., the second region to be bonded 18), no damage is caused to the surface of the base substrate 1 other than the second region to be bonded 18.

Since the third surface 17 (i.e., the back surface of the base substrate 1) is connected to the second surface 14 (i.e., the side surface of the base substrate 1), the third connecting lines 19 formed on the third surface 17 correspond to the second connecting lines 16 formed on the second surface 14, so that the third connecting lines 19 and the second connecting lines 16 are connected to each other at the connecting position between the third surface 17 and the second surface 14, thereby the region to be bonded can be transferred to the third surface 17.

As shown in FIG. 7, when the display panel is an OLED panel, since the OLED display panel has no backlight module, the COF (Chip On Film) substrate 2 is bonded to the base substrate 1 via the third connecting lines 19, that is, the COF substrate 2 is bonded to the base substrate 1 on the back surface of the base substrate 1, so that the bonding does not occupy the peripheral region 12 of the front surface of the base substrate 1, and a narrow border is truly achieved.

A display panel is also provided. The display panel comprises a base substrate, and the base substrate comprises: a first surface provided with a plurality of first connecting lines on at least one side; a second surface connected to the first surface, the second surface comprises a first region to be bonded, wherein a plurality of second connecting lines is arranged in the first region to be bonded, and each of the second connecting lines corresponds to and connects to each of the first connecting lines; and a third surface disposed opposite to the first surface, the third surface comprises a second region to be bonded in which a plurality of third connecting lines are disposed, and each of the third connecting lines corresponds to and connects to each of the second connecting lines.

Specifically, as shown in FIGS. 5 to 7, the base substrate 1 comprises a first surface 11 that is provided with a plurality of first connecting lines 13 on at least one side. Preferably, the first surface 11 may comprise a peripheral region 12, and a plurality of first connecting lines 13 are arranged on one side of the peripheral region 12. The base substrate 1 further comprises a second surface 14 that is connected to the first surface 11. The second surface 14 comprises a first region to be bonded 15 in which a plurality of second connecting lines 16 is disposed. Each of the second connecting lines 16 corresponds to and connects to each of the first connecting lines 13.

The base substrate 1 further comprises a third surface 17 disposed opposite to the first surface 11. The third surface 17 comprises a second region to be bonded 18 in which a plurality of third connecting lines 19 are disposed, and each of the third connecting lines 19 corresponds to and connects to each of the second connecting lines 16.

Preferably, the second region to be bonded 18 is positioned corresponding to the position of the first connecting lines 13.

Preferably, the display panel is an OLED panel.

The display panel of the present disclosure can provide a back side bonding of the base substrate 1. By using the integral transferring and etching method, the line width and pitch of the connecting lines in the region to be bonded can be reduced, which makes it suitable for full-size display panels with a wider range of applications, especially for products with high resolution.

Preferably, the first connecting line 13, the second connecting line 16, and the third connecting line 19 may have a line width of 10 μm to 30 μm, such as 15 μm. Each of the first connecting lines 13, each of the second connecting lines 16, and each of the third connecting lines 19 may have a pitch of 10 μm to 30 μm therebetween respectively, such as 15 μm.

A transferring device 3 is also provided. The transferring device 3 is applied to the aforementioned method for manufacturing a display panel. As shown in FIG. 8, the transferring device 3 comprises: a container 4 for containing the metal liquid 5, a transferring head 6, and an etching apparatus 7 for forming the second connecting lines and/or the third connecting lines. Preferably, the transferring head 6 has the same size as the size of the first region to be bonded 15.

Preferably, the container 4 is an oil cup, an integrally slotted steel container and the like. Preferably, the container 4 has an undivided integral groove structure for containing the metal liquid. The groove structure has a size smaller than the size of the COF substrate 2. In order to ensure the uniformity of the thickness of the first region to be bonded 15 and the second region to be bonded 18, it is preferable that the groove has a bottom flatness of less than 0.1 μm. The groove may have a depth of 6 μm to 8 μm, thereby ensuring the second connecting lines 16 and the third connecting lines 19 have a thickness of 2 μm to 4 μm.

Preferably, the etching apparatus 7 includes a laser etching apparatus, and the laser etching apparatus generates a laser spot with a width of 10 μm to 30 μm (for example, 15 μm), thereby securing the line width of the second connecting lines 16 and the third connecting lines 19, as well as the pitch between each of the second connecting lines 16 and each of the third connecting lines 19 are 10 μm to 30 μm (for example, 15 μm).

The laser etching apparatus may be a laser device that provides a laser with an emitted laser wavelength of 300 nm to 1200 nm, preferably 1064 nm; and a power of 10 W to 50 W, preferably 20 W.

The present disclosure transfers the bonding area originally located on the front surface of the base substrate 1 to the side and back sides of the base substrate 1 by circuit copying technology, and changing the position of the bonding area on the base substrate 1, thereby providing a narrow border around the display panel.

It can be understood that the foregoing embodiments are merely illustrative embodiments employed for describing the principle of the present invention. However, the present invention is not limited thereto. For a person of ordinary skill in the art, various deformations and improvements can be made without departing from the spirit and essence of the present invention. These deformations and modifications shall fall into the protection scope of the present invention.

1. A method for manufacturing a display panel, comprising the following steps:
providing a base substrate having a first surface, wherein a plurality of first connecting lines is arranged on at least one side of the first surface;
transferring a metal liquid for forming second connecting lines onto a second surface of the base substrate by using a transferring device, to cover the entire area of a first region to be bonded, wherein the second surface is connected to the first surface; and
curing the metal liquid in the first region to be bonded, and etching to form a plurality of second connecting lines, such that each of the second connecting lines corresponds to and connects to each of the first connecting lines.

2. The method of claim 1, wherein the etching to form the plurality of second connecting lines comprises: forming the plurality of second connecting lines by laser etching.

3. The method of claim 1 or 2, wherein the method further comprises:
transferring the metal liquid onto a third surface of the base substrate by the transferring device, to form a second region to be bonded, wherein the third surface is disposed opposite to the first surface and is connected to the second surface; and
curing the metal liquid in the second region to be bonded, and etching to form a plurality of third connecting lines, such that each of the third connecting lines corresponds to and connects to each of the second connecting lines.

4. The method according to any one of claims 1 to 3, wherein the curing conditions for curing the metal liquid in the first region to be bonded and/or curing the metal liquid in the second region to be bonded include:
a curing temperature of 100° C. to 130° C., optionally with a curing time of 8 to 10 minutes.

5. The method of claim 3, wherein the etching to form the plurality of third connecting lines comprises: forming the plurality of third connecting lines by laser etching.

6. The method according to any one of claims 1 to 5, wherein the transferring device comprises a container for containing the metal liquid, and a transferring head.

7. The method of claim 6, wherein the container is an oil cup and the metal liquid is injected into the oil cup prior to the transferring, wherein the oil cup preferably has an undivided integral groove structure.

8. The method of claim 6, wherein the transferring head has the same size as a size of the first region to be bonded.

9. The method of claim 6, wherein the transferring the metal liquid for forming second connecting lines onto the second surface of the base substrate by using the transferring device, and/or transferring the metal liquid onto the third surface of the base substrate by the transferring device comprise(s): transferring the metal liquid from the container to the transferring head, and forming the metal liquid on the second surface of the base substrate and/or the third surface of the base substrate by using the transferring head.

10. A display panel comprising a base substrate, the base substrate comprising:
a first surface provided with a plurality of first connecting lines at at least one side;
a second surface connected to the first surface and comprising a first region to be bonded, wherein a plurality of second connecting lines is arranged in the first region to be bonded, and each of the second connecting lines corresponds to and connects to each of the first connecting lines; and
a third surface disposed opposite to the first surface and comprising a second region to be bonded, wherein a plurality of third connecting lines are arranged in the second region to be bonded, and each of the third connecting lines corresponds to and connects to each of the second connecting lines.

11. The display panel of claim 10, wherein the first connecting line, the second connecting line, and the third connecting line each have a line width of 10 μm to 30 μm; and/or,
each of the first connecting lines, each of the second connecting lines, and each of the third connecting lines have a pitch of 10 μm to 30 μm therebetween.

12. The display panel of claim 10 or 11, wherein the display panel is an OLED display panel.

13. The display panel according to any one of claims 10 to 12, wherein the first surface comprises a peripheral region, and the plurality of first connecting lines is arranged at one side of the peripheral region.

14. The display panel of claim 13, wherein the peripheral region has a width of less than or equal to 1 mm.

15. A transferring device applied to the method for manufacturing the display panel according to any one of claims 1 to 9, comprising: a container for containing a metal liquid, a transferring head, and an etching apparatus for forming second connecting lines and/or third connecting lines, wherein the container has an undivided integral groove structure for containing the metal liquid.

16. The transferring device of claim 15, wherein the transferring head has the same size similar as a size of the first region to be bonded.

17. The transferring device of claim 15 or 16, wherein the etching apparatus includes a laser etching apparatus, and the laser etching apparatus generates a laser spot with a width of 10 μm to 30 μm.
